(19) United States
(12) Patent Application Publication
(10) Pub. No.: US 2005/0052214 A1
(43) Pub. Date: Mar. 10, 2005

(54) Level shifter circuit

(76) Inventor: Akihiro Sushihara, Miyazaki (JP)

Correspondence Address: RABIN & Berdo, PC, 1101 14TH STREET, NW, SUITE 500, WASHINGTON, DC, 20005, US

(21) Appl. No.: 10/747,240

(22) Filed: Dec. 30, 2003

(30) Foreign Application Priority Data
Sep. 9, 2003 (JP) 317284/2003

(51) Int. Cl. H03L 5/00

(52) U.S. Cl. 327/333

(57) ABSTRACT

A level shifter circuit which is small in delay in operating speed and also small in power consumption is provided. An NMOS transistor is connected to an input terminal at its source, to an output terminal at its drain, and to a 2V power supply line at its gate. A PMOS transistor is connected to a 3V power supply line at its source and to the output terminal at its drain. Another NMOS transistor is connected to a ground line at its source and to the output terminal at its drain. A control circuit made up of transistors supplies a voltage, which is inverse to the voltage of the input terminal, to the NMOS and PMOS transistors.

### FIELD OF THE INVENTION

The invention relates to a level shifter circuit which is, for example, mounted on two power supply interface compatible semiconductor integrated circuit and so forth.

This application is counterpart of Japanese patent application, Serial Number 317284/2003, filed Sep. 9, 2003, the subject matter of which is incorporated herein by reference.

### BACKGROUND OF THE INVENTION

There has been conventionally known a circuit for converting a high voltage of an input signal, which is called a level shifter circuit. For a level shifter circuit, there is known, for example, a circuit disclosed in paragraphs 0004 to 0008 and illustrated in FIG. 4 of JP-A 1994-283979.

FIG. 31 is a circuit equivalent to the level shifter circuit shown in FIG. 4 of JP-A 1994-283979. As shown in FIG. 31, a level shifter circuit 3100 includes NMOS transistors 3101 to 3103, PMOS transistors 3111 to 3113, an input terminal 3121 and an output terminal 3122. Sources of the PMOS transistors 3111, 3112 are connected to a 3V power supply line vdd3 (e.g., 3.3V), a source of the PMOS transistor 3113 is connected to a 2V power supply line vdd2 (e.g., 2.5V). Sources of the NMOS transistors 3101 to 3103 are connected to a ground line GND (e.g., 0 to 0.4V). Assume that a voltage supplied by the 2V power supply line vdd2 is depicted H2 level, a voltage applied by the 3V power supply line vdd3 is depicted H3 level, a voltage supplied by the ground line GND is depicted L level.

According to the level shifter circuit 3100 in FIG. 31, since an inverter made up of the MOS transistors 3103, 3113 outputs H2 level when the input signal IN goes L level, the NMOS transistor 3102 turns ON, and hence the output signal OUT goes L level. Since the output signal OUT goes L level, the PMOS transistor 3111 turns ON. At this time, since the input signal IN is held L level, the NMOS transistor 3101 is OFF. Accordingly, the PMOS transistor 3112 goes H3 level at its gate voltage, and hence it turns OFF.

Meanwhile, according to the level shifter circuit in FIG. 31, when the input signal IN goes H2 level, the NMOS transistor, 3101 turns ON, and hence the PMOS transistor 3112 turns ON. When the input signal IN goes H2 level, the inverter made up of MOS transistors 3103, 3113 outputs L level, and hence the NMOS transistor 3102 turns OFF. Accordingly, the output signal OUT rises up to H3 level. Accordingly, the PMOS transistor 3111 turns OFF.

In such a manner, the level shifter circuit 3100 in FIG. 31 can output L level when the L level signal is inputted thereto, and can output H3 level when the H2 level signal is inputted. That is, the level shifter circuit 3100 can convert high level from H2 level to H3 level.

However, the conventional level shifter circuit 3100 has a drawback that delay in operating speed is large with much current consumption. Hereinafter described is the reason why this drawback occurrs.

When the input signal IN is changed from H2 level to L level, two-stage transistor (NMOS transistors 3103, 3102) needs to turn ON so as to start the drop of the voltage of the output signal OUT. Since the PMOS transistor 3112 also turns ON when the NMOS transistor 3102 turns ON, a current is discharged from the 3V power supply line vdd3 to the ground line GND. Thereafter, two PMOS transistors 3111, 3112 sequentially turn OFF to stop the discharge of the current.

Likewise, when the input signal IN is changed from L level to H2 level, two stage transistor (NMOS transistors 3101 and PMOS transistor 3112) needs to turn ON so as to start the rise of the voltage of the output signal OUT. Since the PMOS transistor 3111 also turns ON when the NMOS transistor 3101 turns ON, a current is discharged from the 3V power supply line vdd3 to the ground line GND. Thereafter, two MOS transistors 3102, 3111 sequentially turn OFF to stop the discharge of the current.

According to the semiconductor integrated circuit, demand for the improvement of operating speed and the reduction of power consumption is very large. Accordingly, there has been required a level shifter circuit which is small in delay in operating speed and small in power consumption.

### SUMMARY OF THE INVENTION

An object of the invention is to provide a level shifter circuit which is small in delay in operating speed and also small in power consumption.

The level shifter circuit of the invention comprises a first power supply node to which a first power supply voltage is supplied, a second power supply node to which a second power supply voltage, which is greater than the first power supply voltage, is supplied, an input terminal to which an input signal of the first power supply voltage or an input signal of a ground voltage is inputted, an output terminal from which an output signal of the second power supply or an output signal of the ground voltage is outputted, an n-channel first transistor connected to the input terminal at its first electrode, to the output terminal at its second electrode, and to the first power supply node at its control electrode, a p-channel second transistor connected to the second power supply node at its first electrode and to the output terminal at its second electrode, and a control circuit for bringing the second transistor into conduction in response to the input signal of the first power supply voltage inputted to the input terminal, and bringing the second transistor out of conduction in response to the input signal of the ground voltage inputted to the input terminal.

### BRIEF DESCRIPTION OF THE DRAWINGS

FIG. 1 is a circuit diagram showing the configuration of a level shifter circuit according to the first embodiment;

FIG. 2 is a graph showing the result of simulation of operation of the level shifter circuit according to the first embodiment;

FIG. 3 is a graph showing the result of simulation of operation of the level shifter circuit according to the first embodiment;

FIG. 4 is a graph showing the result of simulation of operation of the level shifter circuit according to the first embodiment;

FIG. 5 is a graph showing the result of simulation of operation of the level shifter circuit according to the first embodiment;

FIG. 6 is a graph showing the result of simulation of operation of the level shifter circuit according to the first embodiment;

FIG. 7 is a circuit diagram showing the configuration of a level shifter circuit according to the second embodiment;

FIG. 8 is a graph showing the result of simulation of operation of the level shifter circuit according to the second embodiment;

FIG. 9 is a graph showing the result of simulation of operation of the level shifter circuit according to the second embodiment;

FIG. 10 is a graph showing the result of simulation of operation of the level shifter circuit according to the second embodiment;

FIG. 11 is a graph showing the result of simulation of operation of the level shifter circuit according to the second embodiment;

FIG. 12 is a circuit diagram showing the configuration of a level shifter circuit according to the third embodiment;

FIG. 13 is a graph showing the result of simulation of operation of the level shifter circuit according to the third embodiment;

FIG. 14 is a graph showing the result of simulation of operation of the level shifter circuit according to the third embodiment;

FIG. 15 is a graph showing the result of simulation of operation of the level shifter circuit according to the third embodiment;

FIG. 16 is a graph showing the result of simulation of operation of the level shifter circuit according to the third embodiment;

FIG. 17 is a circuit diagram showing the configuration of a level shifter circuit according to the fourth embodiment;

FIG. 18 is a graph showing the result of simulation of operation of the level shifter circuit according to the fourth embodiment;

FIG. 19 is a graph showing the result of simulation of operation of the level shifter circuit according to the fourth embodiment;

FIG. 20 is a graph showing the the result of simulation of operation of the level shifter circuit according to the fourth embodiment;

FIG. 21 is a graph showing the result of simulation of operation of the level shifter circuit according to the fourth embodiment;

FIG. 22 is a circuit diagram showing the configuration of a level shifter circuit according to the fifth embodiment;

FIG. 23 is a graph showing the result of simulation of operation of the level shifter circuit according to the fifth embodiment;

FIG. 24 is a graph showing the result of simulation of operation of the level shifter circuit according to the fifth embodiment;

FIG. 25 is a graph showing the result of simulation of operation of the level shifter circuit according to the fifth embodiment;

FIG. 26 is a circuit diagram showing the configuration of a level shifter circuit according to the sixth embodiment;

FIG. 27 is a graph showing the result of simulation of operation of the level shifter circuit according to the sixth embodiment;

FIG. 28 is a graph showing the result of simulation of operation of the level shifter circuit according to the sixth embodiment;

FIG. 29 is a graph showing the result of simulation of operation of the level shifter circuit according to the sixth embodiment;

FIG. 30 is a graph showing the result of simulation of operation of the level shifter circuit according to the sixth embodiment; and

FIG. 31 is a circuit diagram showing the configuration of a conventional level shifter circuit.

### BEST MODE FOR CARRYING OUT THE INVENTION

The embodiments of the invention are now described with reference to the attached drawings. In the drawings, the size, shape of each constituent and the arrangement relationship between the constituents are schematically illustrated to the extent that the invention can be understood, and hence numerical values or conditions described hereinafter are mere exemplifications.

First Embodiment

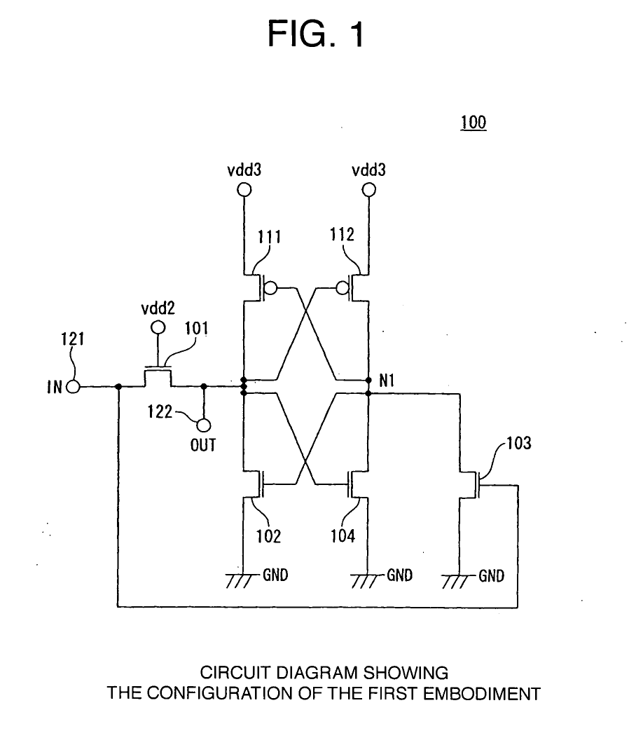

A level shifter circuit of a first embodiment of the invention is now described with reference to FIGS. 1 to 6.

FIG. 1 is a circuit diagram showing the configuration of a level shifter circuit 100 of this embodiment. As shown FIG. 1, the level shifter circuit 100 comprises NMOS transistors 101 to 104 and PMOS transistors 111, 112. The NMOS transistor 103 and an inverter made up of the transistors 104, 112 constitute a control circuit of the invention.

The NMOS transistor 101 (first transistor) is connected to an input terminal 121 at its source, to an output terminal 122 at its drain, and to a 2V power supply line vdd2 (corresponding to first power supply node, e.g., 2.5V) at its gate.

The PMOS transistor 111 (second transistor) is connected to a 3V power supply line vdd3 (corresponding to second power supply node, e.g., 3.3V) at its source, to the output terminal 122 at its drain, and to a node N1 (output node of the control circuit) at its gate.

The NMOS transistor 102 (third transistor) is connected to a ground line GND (corresponding to ground node, e.g., 0 to 0.4V), to the output terminal 122 at its drain, and to a node N1 at its gate.

The NMOS transistor 103 (fourth transistor) is connected to the ground line GND at its source, to the node N1 at its drain, and to the input terminal 121 at its gate.

The NMOS transistor 104 (fifth transistor) is connected to the ground line GND at its source, to the node N1 at its drain, and to the output terminal 122 at its gate.

The PMOS transistor 112 (sixth transistor) is connected to the 3V power supply line vdd3 at its source, to the node N1 at its drain, and to the output terminal 122 at its gate.

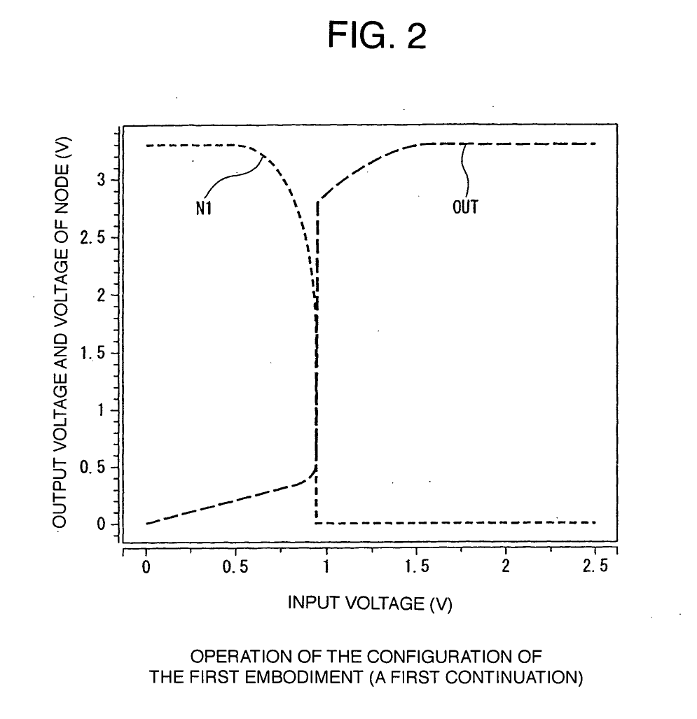

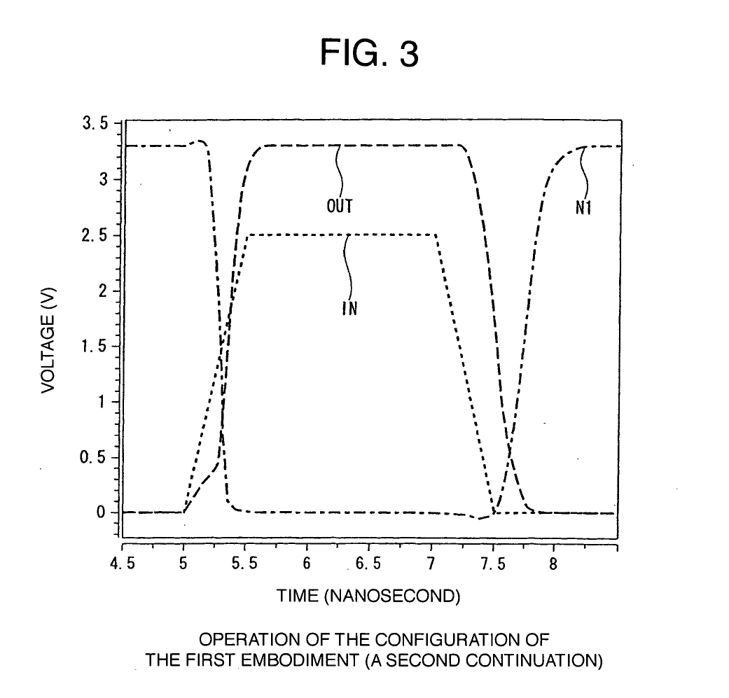

The operation of the level shifter circuit 100 shown in FIG. 1 is now described with reference to FIGS. 2 and 3. FIG. 2 is a graph showing the result of simulation of operation when an input voltage of the level shifter circuit 100 rises. In FIG. 2, a vertical axis shows voltages of an output signal OUT and node N1, and a horizontal axis shows a voltage of an input signal IN. In FIG. 3, a vertical axis shows voltages of the input signal IN, output signal OUT and node N1, and a horizontal axis shows time.

Assume that, in the description set forth hereunder, a voltage supplied by the 2V power supply line vdd2 is H2 level, a voltage supplied by the 3V power supply line vdd3 is H3 level, and a voltage supplied by the ground line GND is L level.

Since the NMOS transistor 101 is connected to the 2V power supply line vdd2 at its gate, it is always ON. Accordingly, when the input signal IN (i.e., voltage of the input terminal 121) is L level, the output signal OUT (i.e., voltage of the output terminal 122) is L level. Further, since the input signal IN and output signal OUT are L level, the NMOS transistors 103, 104 are OFF while the PMOS transistor 112 is ON. Accordingly, the voltage of the node N1 is H3 level. Consequently, the NMOS transistor 102 is ON and the PMOS transistor 111 is OFF.

A case where the input signal IN rises from L level to H2 level is considered. In this case, the voltage of the output signal OUT starts to rise at the same time when the voltage of the input signal IN rises. Consequently, the NMOS transistor 103 turns ON, and the NMOS transistor 104 also turns ON while the PMOS transistor 112 turns OFF Accordingly, the voltage of the node N1 drops. When the voltage of the node N1 is lower than an operating threshold voltage, the PMOS transistor 111 turns ON and the NMOS transistor 102 turns OFF. As a result, the rise of the voltage of the output signal OUT is accelerated to reach H3 level. At this time, the input signal IN is held H2 level due to the effect of voltage drop at the stage of the NMOS transistor 101, and it does not rise up to H3 level. Accordingly, it does not exert an influence upon a pre-stage circuit of the level shifter circuit 100.

A case where the input signal IN drops from H2 level to L level is next considered. In this case, the voltage of the output signal OUT starts to drop at the same time when the voltage of the input signal IN drops. Accordingly, the NMOS transistor 103 turns OFF and the NMOS transistor 104 also turns OFF while the PMOS transistor 112 turns ON. As a result, the voltage of the node N1 rises. Accordingly, the NMOS transistor 102 turns ON and the PMOS transistor 111 turns OFF. As a result, the voltage of the output signal OUT drops to complete L level.

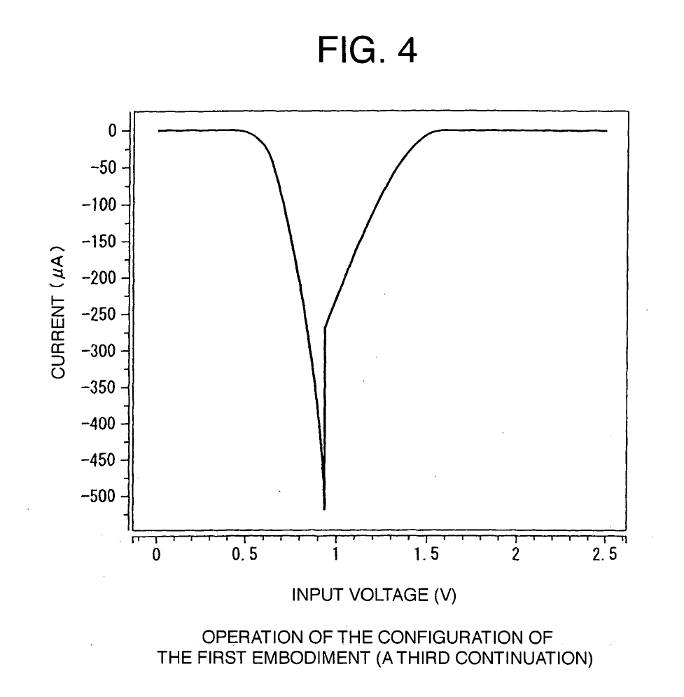

FIG. 4 is a graph showing the result of simulation of current consumption when the input voltage of the level shifter circuit 100 rises. In FIG. 4, a vertical axis show a value of the current flowing out from the 3V power supply line vdd3, and a horizontal axis shows the voltage of the input signal IN.

As is understood from FIG. 4, when the input signal IN rises from 0.5 V to 1.5 V, a current flows out from the 3V power supply line vdd3. This is mainly the current to be supplied from the 3V power supply line vdd3 to the PMOS transistor 111. However, since the NMOS transistor 102 turns OFF at substantially the same time when the PMOS transistor 111 effects ON operation, as described above, a through current, i.e., the current flowing through the transistors 111, 102 is substantially zero. Further, as is understood from FIG. 4, the current flowing out from the 3V power supply line vdd3 is zero when the input signal IN is L level and H level. Accordingly, the power consumption of the level shifter circuit 100 is very small.

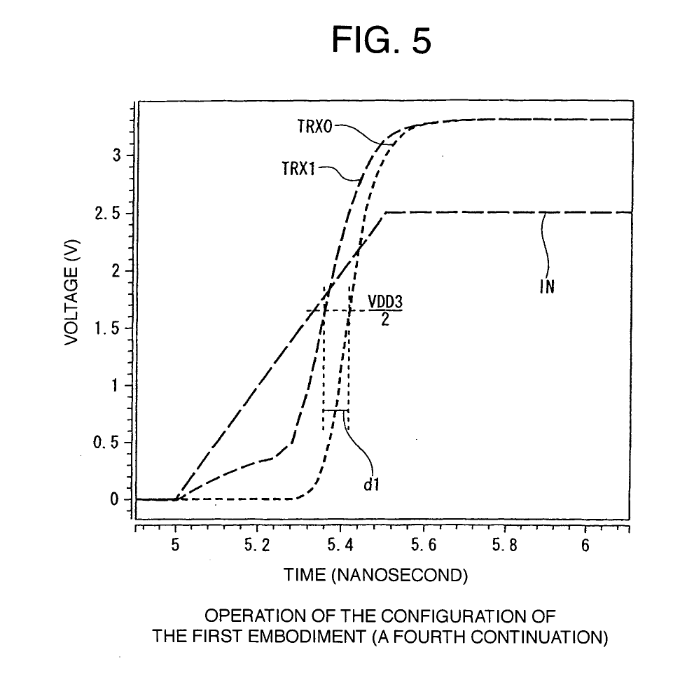

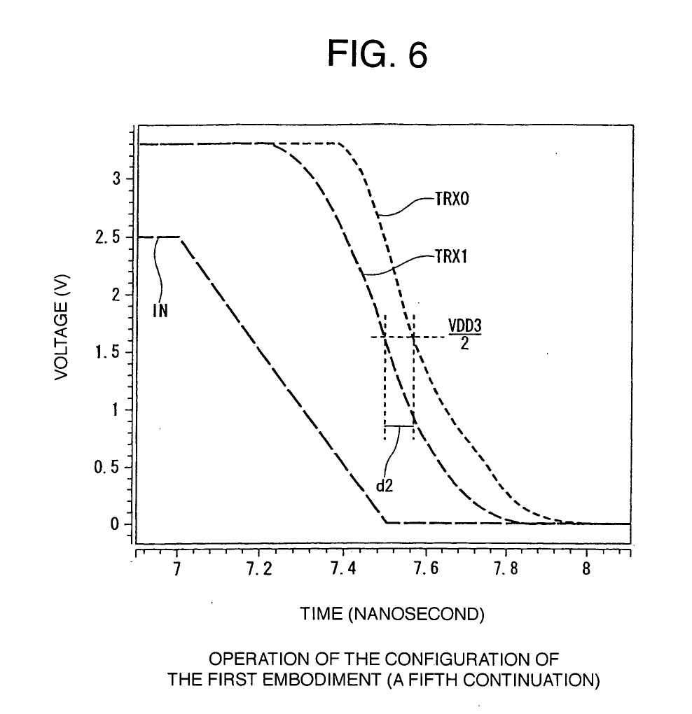

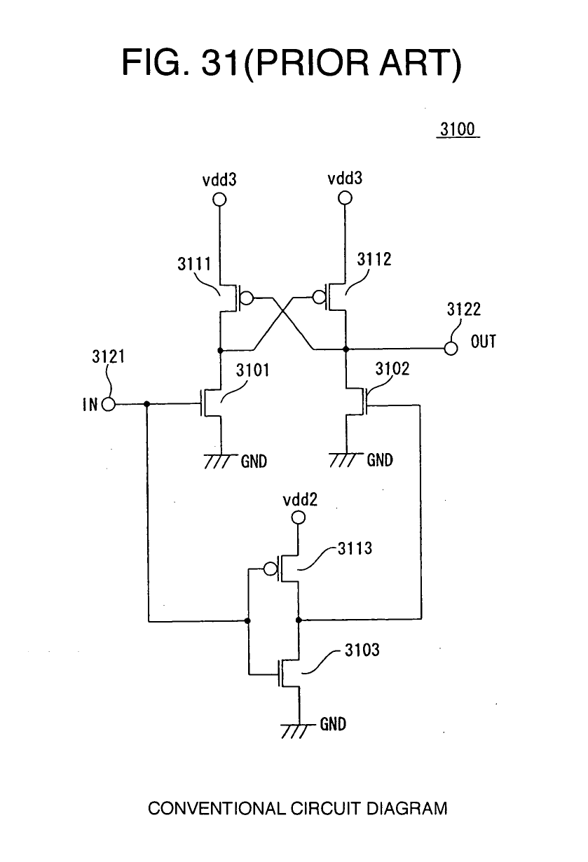

FIGS. 5 and 6 are graphs showing the result of simulation of operation of the level shifter circuit 100 of this embodiment and that of the conventional level shifter circuit 3100 (see FIG. 31). FIG. 5 is a case where the voltage of the input signal IN rises while FIG. 6 is a case where the voltage of the input signal IN drops. In FIGS. 5 and 6, a vertical axis shows a voltage and a horizontal axis shows time. A curve TRX0 shows the output voltage of the conventional level shifter circuit 3100 and a curve TRX1 shows the output voltage of the level shifter circuit 100 of this embodiment. Depicted by VDD3 is a supply voltage of the 3V power supply line vdd3.

As is understood from FIG. 5, according to the level shifter circuit 100 of this embodiment, the voltage of the output signal OUT starts to rise at substantially the same time when the voltage of the input signal IN starts to rise. The time required for the voltage of the output signal OUT in the level shifter circuit 100 to reach VDD3/2 is shorter than that in the conventional level shifter circuit 3100 by d1.

As is understood from FIG. 6, the drop of the voltage of the output signal OUT in the level shifter circuit 100 starts earlier than that in the level shifter circuit 3100. The time required for the voltage of the output signal OUT in the level shifter circuit 100 to reach VDD3/2 is shorter than that in the conventional level shifter circuit 3100 by d2.

As described above, according to this embodiment, since the level shifter circuit has the NMOS transistor 101 which is connected to the 2V power supply line vdd2 at its gate, when the input signal IN of the GND level is inputted to the input terminal 121, the signal of the GND level is delivered to the output terminal OUT via the NMOS transistor 101 and the signal of the GND level is instantaneously outputted from the output terminal OUT. Further, according this embodiment, since the level shifter circuit has the NMOS transistor 101, when the input signal IN of the H2 level (first power supply voltage level) is inputted to the input terminal 121, the output terminal OUT instantaneously goes a level close to the H2 level. Further, since the level shifter circuit has the PMOS transistor 111 connected between the 3V power supply line vdd3 and the output terminal OUT, and the control circuit for controlling a conductive state of the PMOS transistor 111 in response to the input signal IN, the voltage of the output terminal OUT which goes H2 level rises up to H3 level (second power supply voltage level). In such a manner the level shifter circuit of this embodiment can be speeded up in operating speed.

As mentioned in detail above, according to this embodiment, it is possible to provide the level shifter circuit which is small in power consumption and speeded up in operating speed.

Second Embodiment:

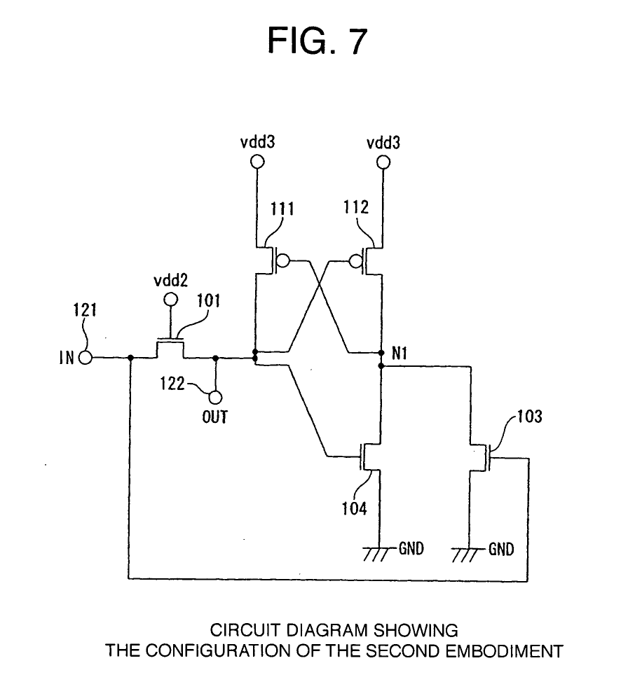

A level shifter circuit according to a second embodiment is now described with reference FIGS. 7 to 11.

FIG. 7 is a circuit diagram showing the configuration of a level shifter circuit 700 of this embodiment. In FIG. 7, the constituents of the level shifter circuit 700 which are the same as those of the level shifter circuit 100 in FIG. 1 are depicted by the same reference numerals. That is, the level shifter circuit 700 is different from the level shifter circuit 100 in that the level shifter circuit 700 has no NMOS transistor 102 (third transistor).

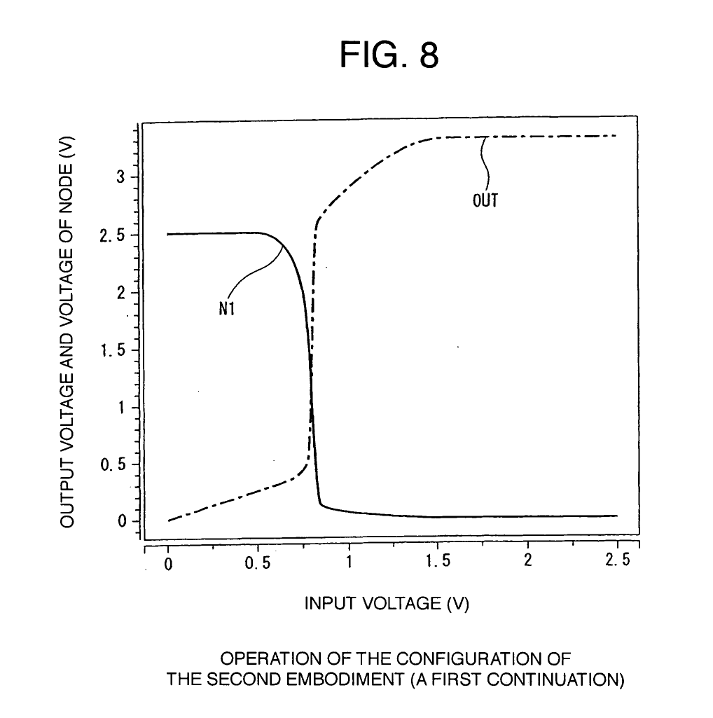

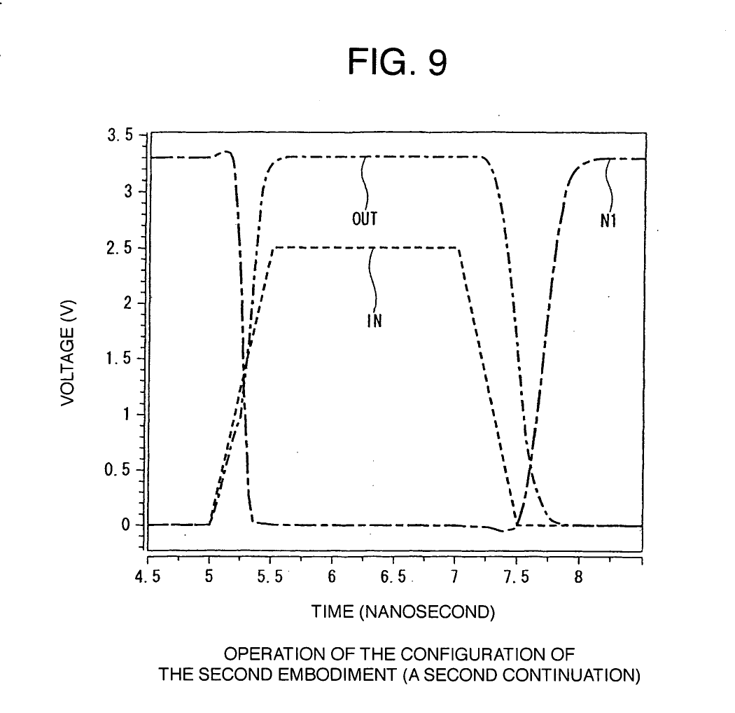

The operation of the level shifter circuit 700 shown in FIG. 7 is now described with reference to FIGS. 8 and 9. FIG. 8 is a graph showing the result of simulation of operation when an input voltage of the level shifter circuit 700 rises. In FIG. 8, a vertical axis shows voltages of an output signal OUT and node N1, and a horizontal axis shows a voltage of an input signal IN. In FIG. 9, a vertical axis shows voltages of the input signal IN, output signal OUT and node N1, and a horizontal axis shows time.

Assume that, in the description set forth hereunder, a voltage supplied by a 2V power supply line vdd2 is H2 level, a voltage supplied by a 3V power supply line vdd3 is H3 level, and a voltage supplied by a ground line GND is L level.

Since an NMOS transistor 101 is connected to the 2V power supply, line vdd2 at its gate, it is always ON. Accordingly, when the input signal IN is L level, the output signal OUT is L level. Further, since the input signal IN and output signal OUT are L level, NMOS transistors 103, 104 are OFF while a PMOS transistor 112 is ON. Accordingly, the voltage of the node N1 is H3 level. Consequently, a PMOS transistor 111 is OFF.

A case where the input signal IN rises from L level to H2 level is considered. In this case, the voltage of the output signal OUT starts to rise at the same time when the voltage of the input signal IN rises. Consequently, the NMOS transistor 103 turns ON, and the NMOS transistor 104 also turns ON while the PMOS transistor 112 turns OFF. Accordingly, the voltage of the node N1 drops. Accordingly, the PMOS transistor 111 turns ON. As a result, the rise of the voltage of the output signal OUT is accelerated to reach H3 level. At this time, the input signal IN is held H2 level due to the effect of voltage drop at the stage of the NMOS transistor 101, and it does not rise up to H3 level. Accordingly, it does not exert an influence upon a pre-stage circuit of the level shifter circuit 700.

A case where the input signal IN drops from H2 level to L level is next considered. In this case, the voltage of the output signal OUT starts to drop at the same time when the voltage of the input signal IN drops. Consequently, the NMOS transistor 103 turns OFF and the NMOS transistor 104 also turns OFF while the PMOS transistor 112 turns ON. Accordingly, the voltage of the node N1 goes H3 level, and hence the PMOS transistor 111 turns OFF. As a result, the voltage of the output signal OUT drops to complete L level.

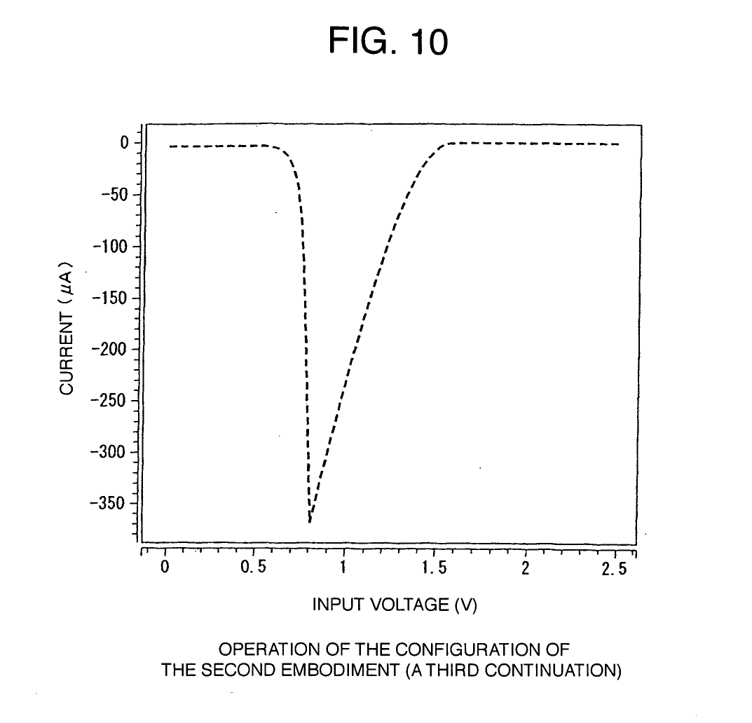

FIG. 10 is a graph showing the result of simulation of current consumption when the input voltage of the level shifter circuit 700 rises. In FIG. 10, a vertical axis show a value of the current flowing out from the 3V power supply line vdd3, and a horizontal axis shows the voltage of the input signal IN.

As is understood from FIG. 10, when the input signal IN rises from 0.5 V to 1.5 V, a current flows out from the 3V power supply line vdd3. This is mainly the current to be supplied to the PMOS transistor 111. Further, as is understood from FIG. 10, the power consumption when the input signal IN is L level and H level is substantially zero. Accordingly, the power consumption of the level shifter circuit 700 is very small.

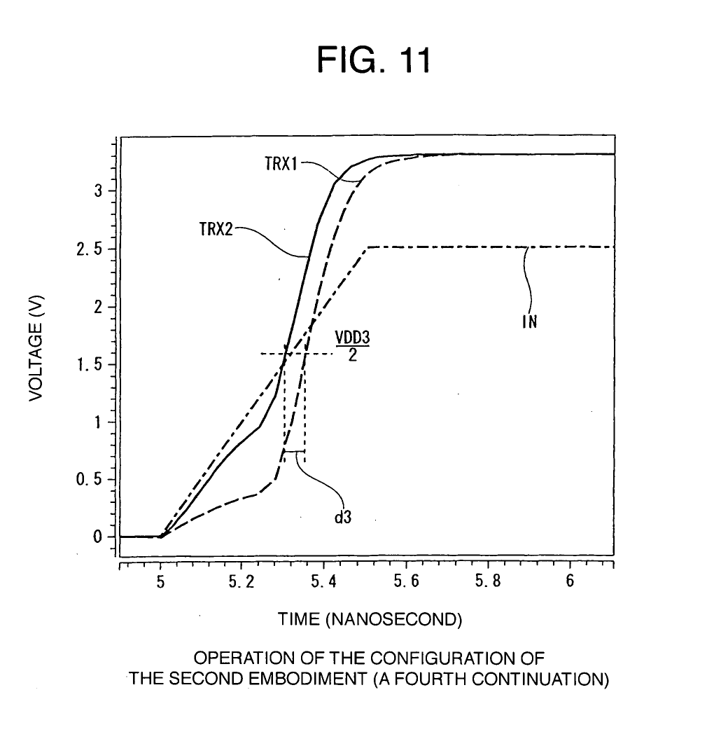

FIG. 11 is a graph showing the result of simulation of operation of the level shifter circuit 700 of this embodiment and the level shifter circuit 100 (see FIG. 1) of the first embodiment. FIG. 11 shows a case where the voltage of the input signal IN rises. In FIG. 11, a vertical axis shows a voltage and a horizontal axis shows time. A curve TRX1 shows the output voltage of the level shifter circuit 100 and a curve TRX2 shows the output voltage of the level shifter circuit 700. Depicted by VDD3 is a supply voltage of the 3V power supply line vdd3.

As is understood from FIG. 11, of the level shifter circuit 700 of this embodiment, the voltage of the output signal OUT rises in substantially the same inclination as the voltage of the input signal IN rises. The time required for the voltage of the output signal OUT in the level shifter circuit 700 to reach VDD3/2 is shorter than that in the level shifter circuit 100 by d3. This is caused by the fact that the level shifter circuit 700 of this embodiment has no NMOS transistor 102 whereupon a current flows out from the NMOS transistor 102 when the voltage of the output signal OUT rises in the level shifter circuit 100 of the first embodiment.

In such a manner, the operating time when the output signal OUT rises can be further speed up without using the NMOS transistor 102 (FIG. 1).

As mentioned in detail above, according to this embodiment, it is possible to provide the level shifter circuit which is small in power consumption and speeded up in operating speed.

Third Embodiment:

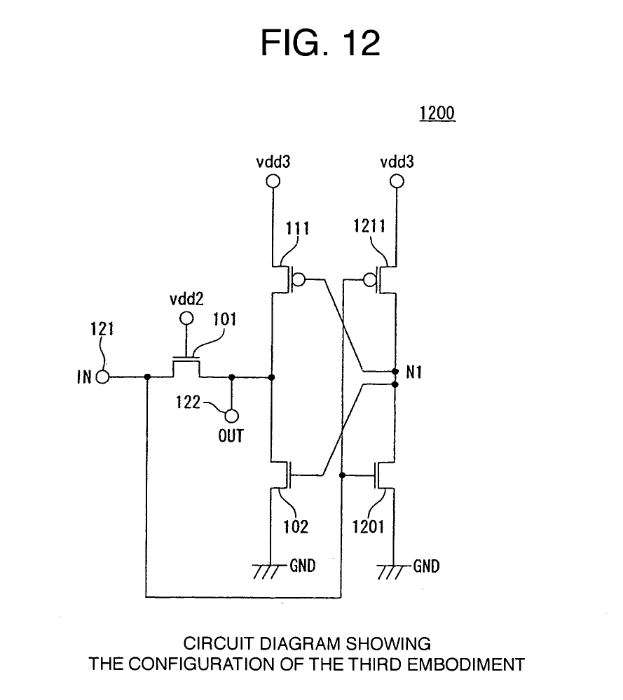

A level shifter circuit according to a third embodiment is now described with reference FIGS. 12 to 16.

FIG. 12 is a circuit diagram showing the configuration of a level shifter circuit 1200 of this embodiment. In FIG. 12, the constituents of the level shifter circuit 1200 which are the same as those of the level shifter circuit 100 in FIG. 1 are depicted by the same reference numerals. That is, the level shifter circuit 1200 of this embodiment is different from the first and second embodiments in that the level shifter circuit 1200 has a control circuit made (up of transistors 1201, 1211).

The NMOS transistor 1201 (seventh transistor) is connected to a ground line GND at its source, to an node N1 at its drain, and to an input terminal 121 at its gate.

The PMOS transistor 1211 (eighth transistor) is connected to a 3V power supply line vdd3 at its source, to the node N1 at its drain, and to the input terminal 121 at its gate.

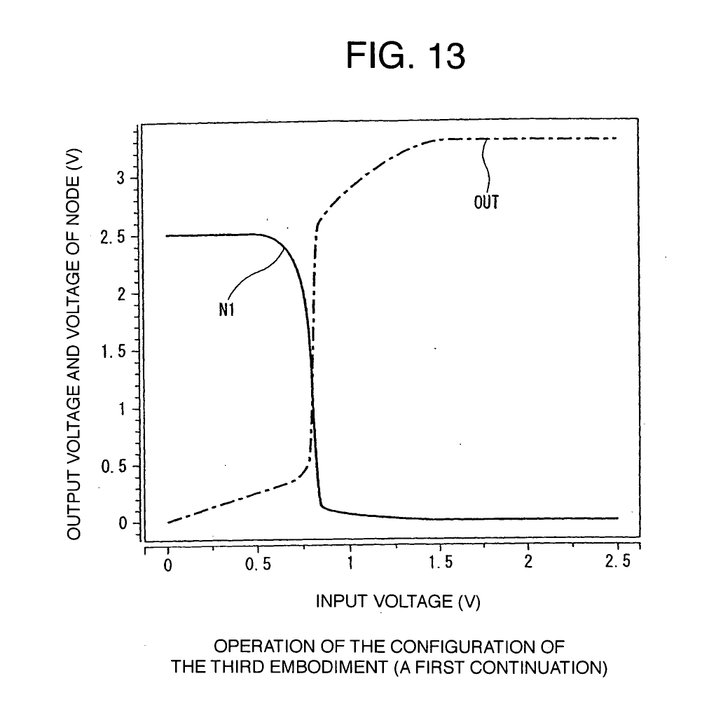

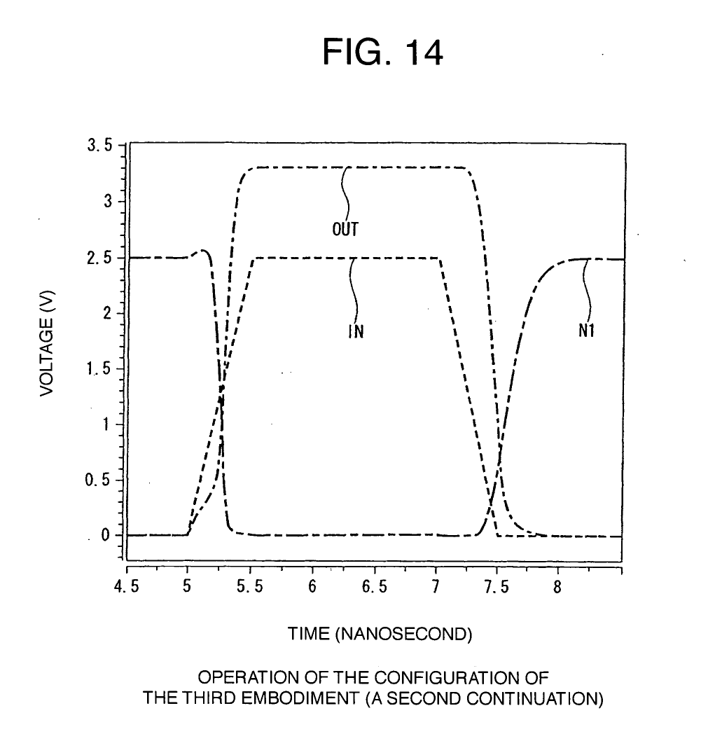

The operation of the level shifter circuit 1200 shown in FIG. 12 is now described with reference to FIGS. 13 and 14. FIG. 13 is a graph showing the result of simulation of operation when an input voltage of the level shifter circuit 1200 rises. In FIG. 13, a vertical axis shows voltages of an output signal OUT and node N1, and a horizontal axis shows a voltage of an input signal IN. In FIG. 14, a vertical axis shows voltages of the input signal IN, output signal OUT and node N1, and a horizontal axis shows time.

Assume that, in the description set forth hereunder, a voltage supplied by a 2V power supply line vdd2 is H2 level, a voltage supplied by the 3V power supply line vdd3 is H3 level, and a voltage supplied by the ground line GND is L level.

Since an NMOS transistor 101 is connected to the 2V power supply line vdd2 at its gate, it is always ON. Accordingly, when the input signal IN is L level, the output signal OUT is L level. Further, since the input signal IN is L level, the NMOS transistor 1201 is OFF and the PMOS transistor 1211 is also ON. Accordingly, the voltage of the node N1 is H3 level. Consequently, an NMOS transistor 102 is ON and a PMOS transistor 111 is OFF.

A case where the input signal IN rises from L level to H2 level is considered. In this case, the voltage of the output signal OUT starts to rise at the same time when the voltage of the input signal IN rises. Further, since the voltage of the input signal IN rises, the voltages of the gates of the transistors 1201, 1211 also rise. Subsequently, when the voltages of these gates are higher than an operating threshold voltage, the NMOS transistor 1201 turns ON and the PMOS transistor 1211 turns OFF. Consequently, the voltage of the node N1 drops. When the voltage of the node N1 is lower than the operating threshold voltage, the NMOS transistor 102 turns OFF and the PMOS transistor 111 turns ON. Consequently, the rise of the voltage of the output signal OUT is accelerated to reach H3 level. At this time, the input signal IN is held H2 level due to the effect of voltage drop at the stage of the NMOS transistor 101, and it does not rise up to H3 level. Accordingly, it does not exert an influence upon a pre-stage circuit of the level shifter circuit 1200.

A case where the input signal IN drops from H2 level to L level is next considered. In this case, the voltage of the output signal OUT starts to drop at the same time when the voltage of the input signal IN drops. Subsequently, when the voltage of the input signal IN is lower than the operating threshold voltage, the NMOS transistor 1201 turns OFF and the PMOS transistor 1211 turns ON, and hence the voltage of the node N1 rises up to H3 level. Accordingly, the NMOS transistor 102 turns ON and the PMOS transistor 111 turns OFF. As a result, the voltage of the output signal OUT drops to complete L level.

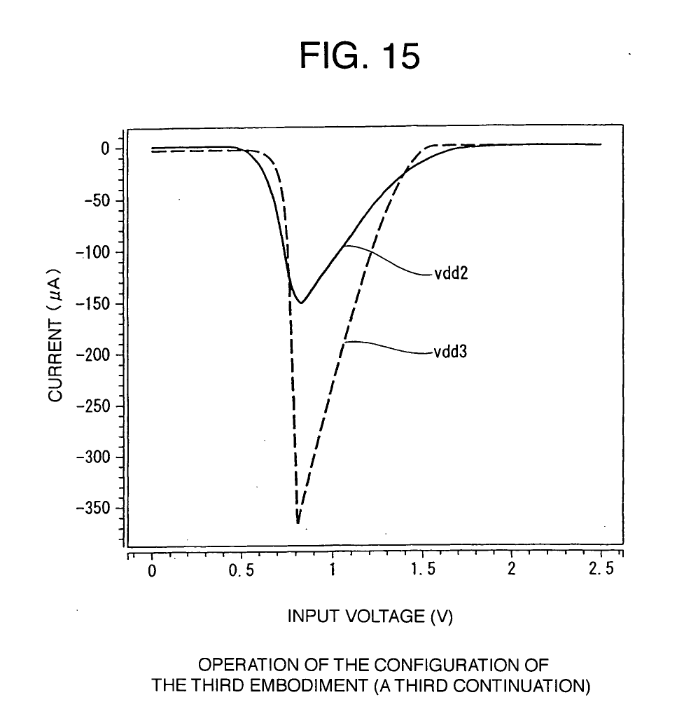

FIG. 15 is a graph showing the result of simulation of current consumption when the input voltage of the level shifter circuit 1200 rises. In FIG. 15, a vertical axis show values of the currents flowing out from the 2V, 3V power supply lines vdd2, vdd3, and a horizontal axis shows the voltage of the input signal IN.

As is understood from FIG. 15, when the input signal IN rises from 0.5 V to 1.5 V, currents flow out from the 2V, 3V power supply lines vdd2, vdd3. According to this embodiment, since the transistors 1201, 1211 operate at the same time and the transistors 102, 111 also operate at the same time, a through current is not substantially generated. Further, as is understood from FIG. 15, a power consumption is substantially zero when the input signal IN is L level and H2 level. Accordingly, the power consumption of the level shifter circuit 1200 is very small.

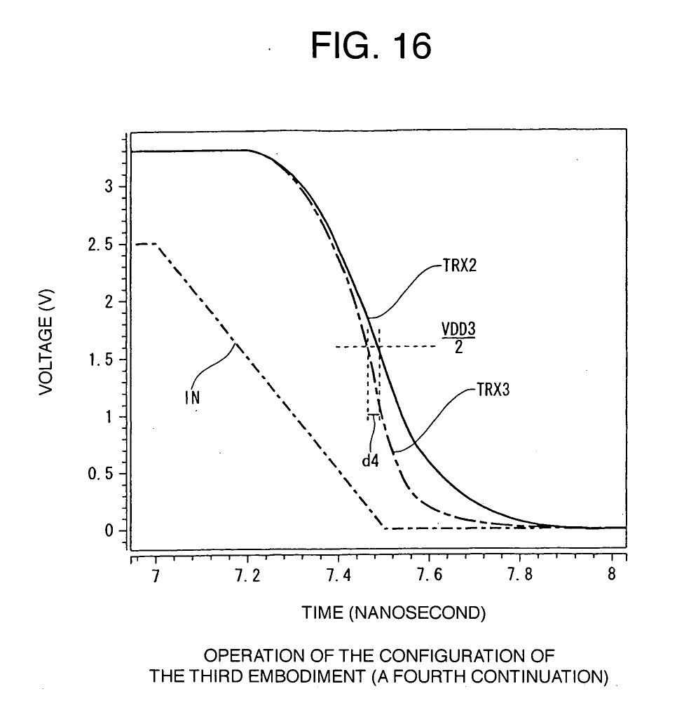

FIG. 16 is a graph showing the result of simulation of operation of the level shifter circuit 1200 of this embodiment and the level shifter circuit 700 (see FIG. 7) of the second embodiment. FIG. 16 is a case where the voltage of the input signal IN drops. In FIG. 16, a vertical axis shows a voltage and a horizontal axis shows time. A curve TRX2 shows the output voltage of the level shifter circuit 700 and a curve TRX3 shows the output voltage of the level shifter circuit 1200. Depicted by VDD3 is a supply voltage of the 3V power supply line vdd3.

As is understood from FIG. 16, according to the level shifter circuit 1200 of this embodiment, the voltage of the output signal OUT drops faster than that of the level shifter circuit 700. The time required for the voltage of the output signal OUT in the level shifter circuit 1200 to reach VDD3/2 is shorter than that in the level shifter circuit 700 by d4.

In such a manner, according to this embodiment, operation time when the output signal OUT falls can be further speeded up.

As mentioned in detail above, according to this embodiment, it is possible to provide the level shifter circuit which is small in power consumption and speeded up in operating speed.

Fourth Embodiment:

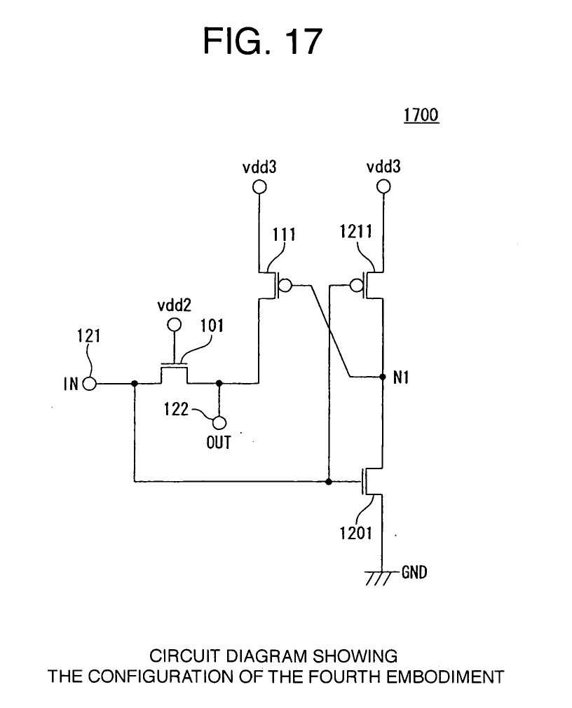

A level shifter circuit according to a fourth embodiment is now described with reference FIGS. 17 to 21.

FIG. 17 is a circuit diagram showing the configuration of a level shifter circuit 1700 of this embodiment. In FIG. 17, the constituents of the level shifter circuit 1700 which are the same as those of the level shifter circuit 1200 in FIG. 12 are depicted by the same reference numerals. That is, the level shifter circuit 1700 of this embodiment is different from the level shifter circuit 1200 in that the level shifter circuit 1700 has no NMOS transistor 102 (third transistor of the invention).

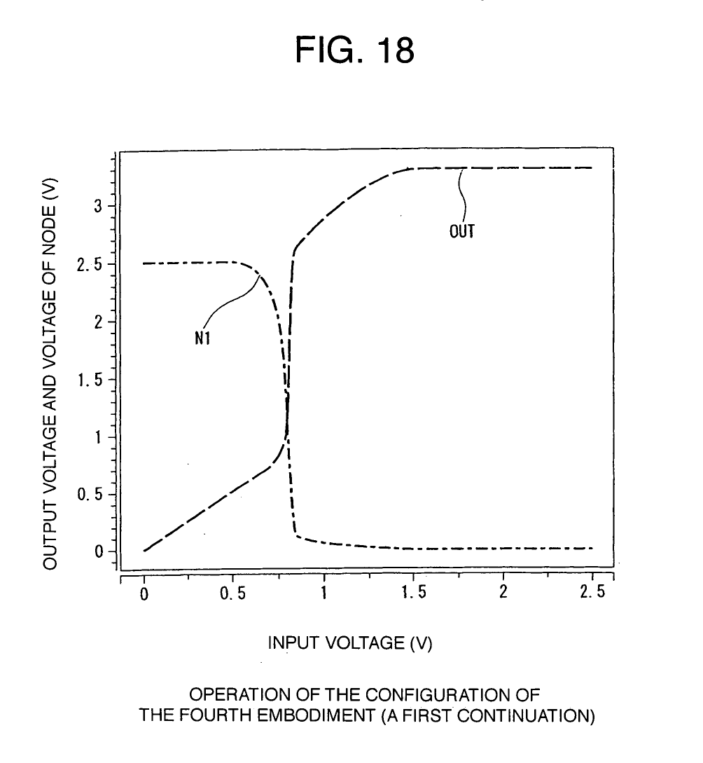

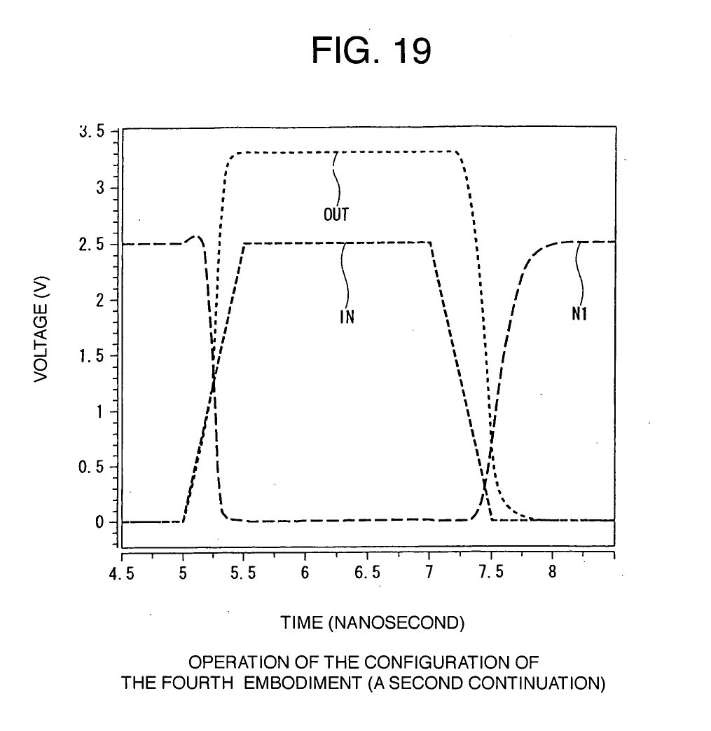

The operation of the level shifter circuit 1700 shown in FIG. 17 is now described with reference to FIGS. 18 and 19. FIG. 18 is a graph showing the result of simulation of operation when an input voltage of the level shifter circuit 1700 rises. In FIG. 18, a vertical axis shows voltages of an output signal OUT and node N1, and a horizontal axis shows a voltage of an input signal IN. In FIG. 19, a vertical axis shows voltages of the input signal IN, output signal OUT and node N1, and a horizontal axis shows time.

Assume that, in the description set forth hereunder, a voltage supplied by a 2V power supply line vdd2 is H2 level, a voltage supplied by a 3V power supply line vdd3 is H3 level, and a voltage supplied by a ground line GND is L level.

Since an NMOS transistor 101 is connected to the 2V power supply line vdd2 at its gate, it is always ON. Accordingly, when the input signal IN is L level, the output signal OUT is L level. Further, since the input signal IN is L level, an NMOS transistor 1201 is OFF while a PMOS transistor 1211 is ON. Accordingly, the voltage of the node N1 is H3 level. Consequently, a PMOS transistor 111 is OFF.

A case where the input signal IN rises from L level to H2 level is considered. In this case, the voltage of the output signal OUT starts to rise at the same time when the voltage of the input signal IN rises. Further, since the voltage of the input signal IN rises, the voltages of the gates of the transistors 1201, 1211 also rise. Subsequently, when the voltages of these gates are higher than an operating threshold voltage, the NMOS transistor 1201 turns ON and the PMOS transistor 1211 turns OFF. Consequently, the voltage of the node N1 drops. When the voltage of the node N1 is lower than the operating threshold voltage, the PMOS transistor 111 turns ON. Consequently, the rise of the voltage of the output signal OUT is accelerated to reach H3 level. At this time, the input signal IN is held H2 level due to the effect of voltage drop at the stage of the NMOS transistor 101, and it does not rise up to H3 level. Accordingly, it does not exert an influence upon a pre-stage circuit of the level shifter circuit 1700.

A case where the input signal IN drops from H2 level to L level is next considered. In this case, the voltage of the output signal OUT starts to drop at the same time when the voltage of the input signal IN drops. Subsequently, when the voltage of the input signal IN is lower than the operating threshold voltage, the NMOS transistor 1201 turns OFF and the PMOS transistor 1211 turns ON, and hence the voltage of the node N1 rises up to H3 level. Accordingly, the PMOS transistor 111 turns OFF. As a result, the voltage of the output signal OUT drops to complete L level.

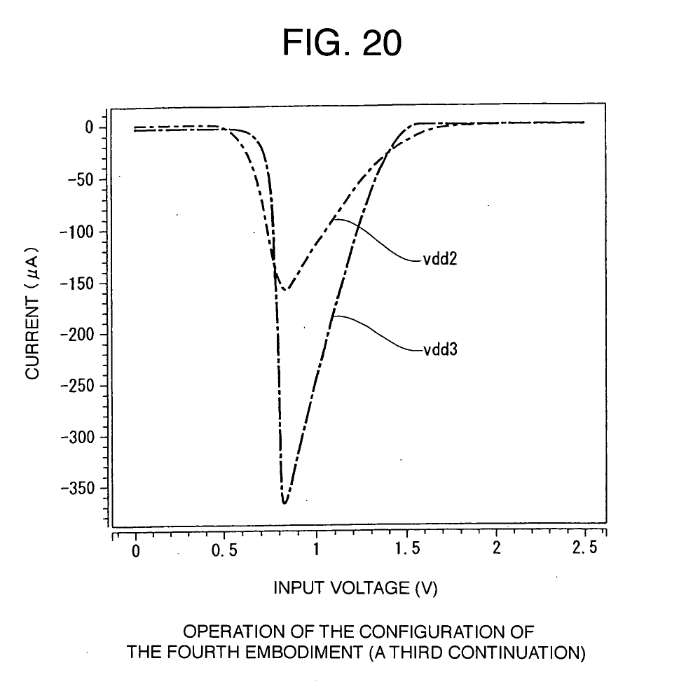

FIG. 20 is a graph showing the result of simulation of current consumption when the input voltage of the level shifter circuit 1700 rises. In FIG. 20, a vertical axis show a value of the current flowing out from the 2V, 3V power supply lines vdd2, vdd3, and a horizontal axis shows the voltage of the input signal IN.

As is understood from FIG. 20, when the input signal IN rises from 0.5 V to 1.5 V, currents flow out from the 2V, 3V power supply lines vdd2, vdd3. Since the transistors 1201, 1211 operate at the same time even in the embodiment, a through current is not substantially generated. Further, as is understood from FIG. 20, a power consumption is substantially zero when the input signal IN is L level and H2 level. Accordingly, the power consumption of the level shifter circuit 1700 is very small.

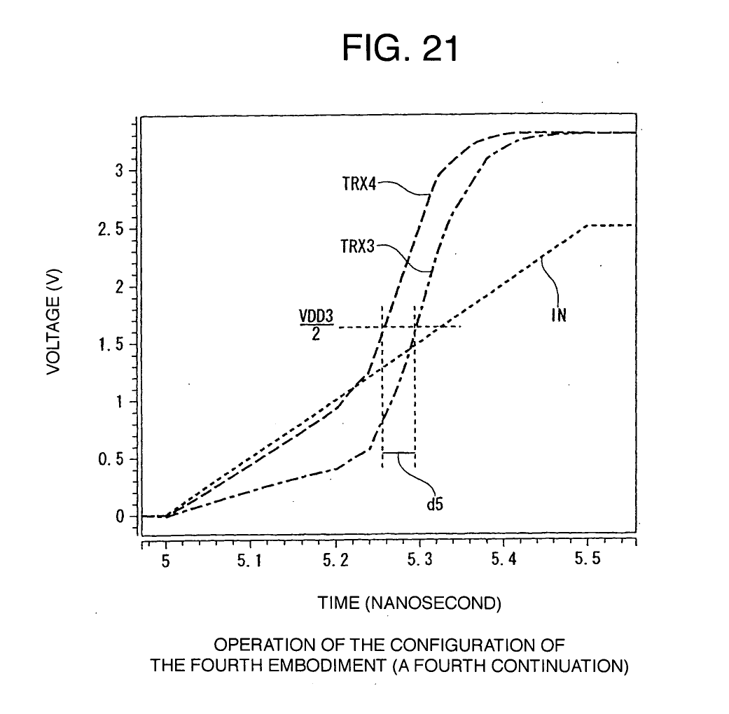

FIG. 21 is a graph showing the result of simulation of operation of the level shifter circuit 1700 of this embodiment and the level shifter circuit 1200 (see FIG. 12) of the third embodiment. FIG. 21 is a case where the voltage of the input signal IN rises. In FIG. 21, a vertical axis shows a voltage and a horizontal axis shows time. A curve TRX3 shows the output voltage of the level shifter circuit 1200 and a curve TRX4 shows the output voltage of the level shifter circuit 1700. Depicted by VDD3 is a supply voltage of the 3V power supply line vdd3.

As is understood from FIG. 21, according to the level shifter circuit 1700 of this embodiment, the voltage of the output signal OUT rises faster than that of the level shifter circuit 1200. The time required for the voltage of the output signal OUT in the level shifter circuit 1700 to reach VDD3/2 is shorter than that in the level shifter circuit 1200 by d5.

In such a manner, according to this embodiment, the operation time when the output signal OUT rises can be further speed up. This is caused by the fact that the level shifter circuit 1700 of this embodiment has no NMOS transistor 102 whereupon a current flows out from the NMOS transistor 102 when the voltage of the output signal OUT rises in the level shifter circuit 1200 of the third embodiment.

As mentioned in detail above, according to this embodiment, it is possible to provide the level shifter circuit which is small in power consumption and speeded up in operating speed.

Fifth Embodiment:

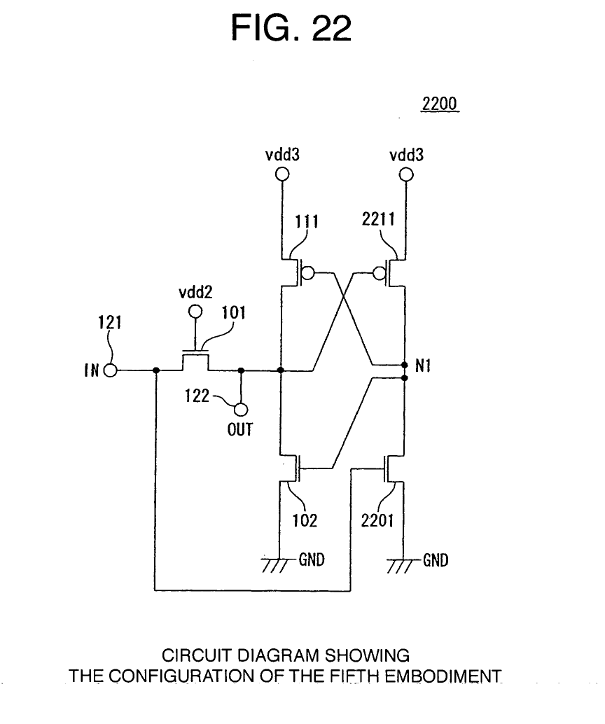

A level shifter circuit according to a fifth embodiment is now described with reference FIGS. 22 to 25.

FIG. 22 is a circuit diagram showing the configuration of a level shifter circuit 2200 of this embodiment. In FIG. 22, the constituents of the level shifter circuit 2200 which are the same as those of the level shifter circuit 100 in FIG. 1 are depicted by the same reference numerals. That is, the level shifter circuit 2200 of the invention is different from the first to fourth embodiments in that the level shifter circuit 2200 has a control circuit (made up of transistors 2201, 2211).

The NMOS transistor 2201 (ninth transistor) is connected to a ground line GND at its source, to an node N1 at its drain, and to an input terminal 121 at its gate.

The PMOS transistor 2211 (tenth transistor) is connected to a 3V power supply line vdd3 at its source, to the node N1 at its drain, and to an output terminal 122 at its gate.

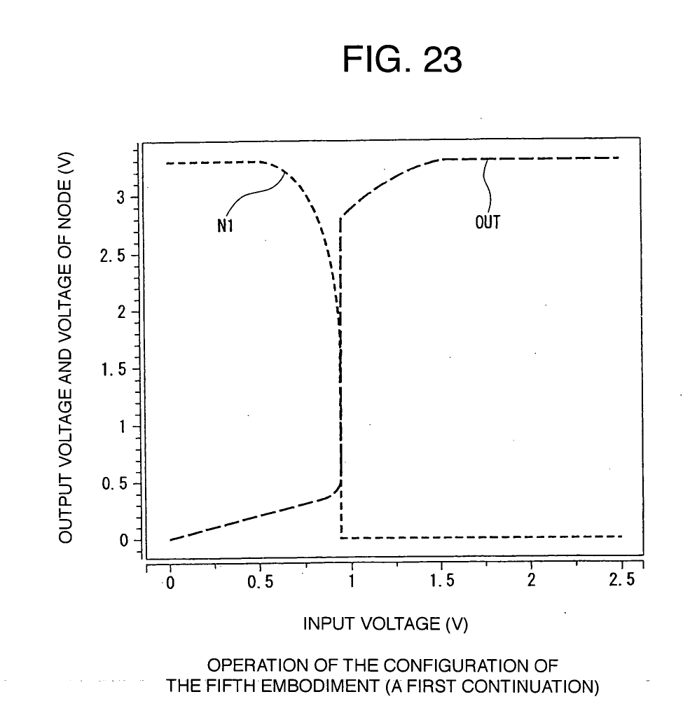

The operation of the level shifter circuit 2200 shown in FIG. 22 is now described with reference to FIG. 23. FIG. 23 is a graph showing the result of simulation of operation when an input voltage of the level shifter circuit 2200 rises. In FIG. 23, a vertical axis shows voltages of an output signal OUT and node N1, and a horizontal axis shows a voltage of an input signal IN.

Assume that, in the description set forth hereunder, a voltage supplied by a 2V power supply line vdd2 is H2 level, a voltage supplied by the 3V power supply line vdd3 is H3 level, and a voltage supplied by the ground line GND is L level.

Since an NMOS transistor 101 is connected to the 2V power supply line vdd2 at its gate, it is always ON. Accordingly, when the input signal IN is L level, the output signal OUT is L level. Further, since the input signal IN and output signal OUT are L level, the NMOS transistor 2201 is OFF and the PMOS transistor 2211 is ON. Accordingly, the voltage of the node N1 is H3 level. Consequently, an NMOS transistor 102 is ON and a PMOS transistor 111 is OFF.

A case where the input signal IN rises from L level to H2 level is considered. In this case, the voltage of the output signal OUT starts to rise at the same time when the voltage of the input signal IN rises. Consequently, the voltages of the gates of the transistors 2201, 2211 also rise. Subsequently, when the voltages of these gates are higher than an operating threshold voltage, the NMOS transistor 2201 turns ON and the PMOS transistor 2211 turns OFF. Accordingly, the voltage of the node N1 drops, and hence the NMOS transistor 102 turns OFF and the PMOS transistor 111 turns ON. Consequently, the rise of the voltage of the output signal OUT is accelerated to reach H3 level. At this time, the input signal IN is held H2 level due to the effect of voltage drop at the stage of the NMOS transistor 101, and it does not rise up to H3 level. Accordingly, it does not exert an influence upon a pre-stage circuit of the level shifter circuit 2200.

A case where the input signal IN drops from H2 level to L level is next considered. In this case, the voltage of the output signal OUT starts to drop at the same time when the voltage of the input signal IN drops. Accordingly, the NMOS transistor 2201 turns OFF and the PMOS transistor 2211 turns ON, and hence the voltage of the node N1 goes H3 level. When the voltage of the node N1 goes H3 level, the NMOS transistor 102 turns ON and the PMOS transistor 111 turns OFF. As a result, the voltage of the output signal OUT drops to complete L level.

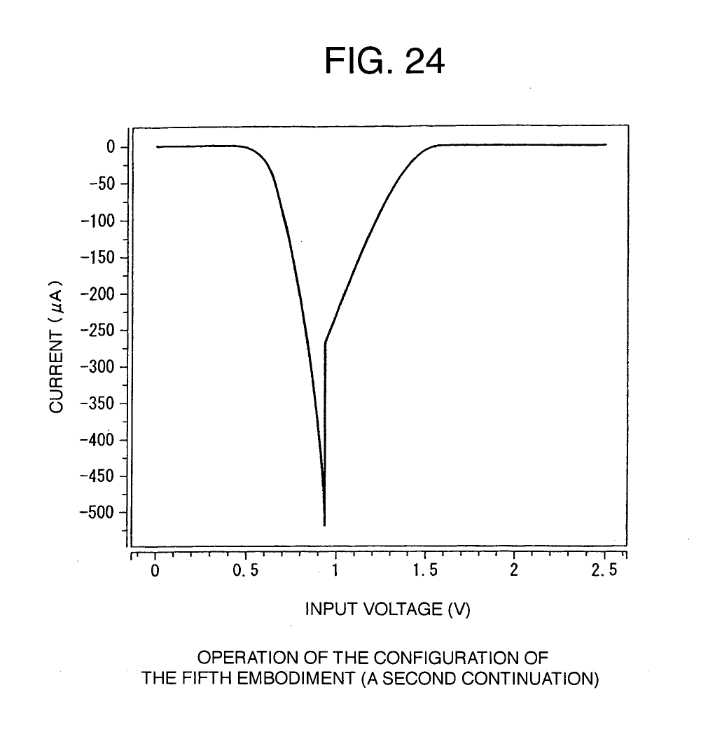

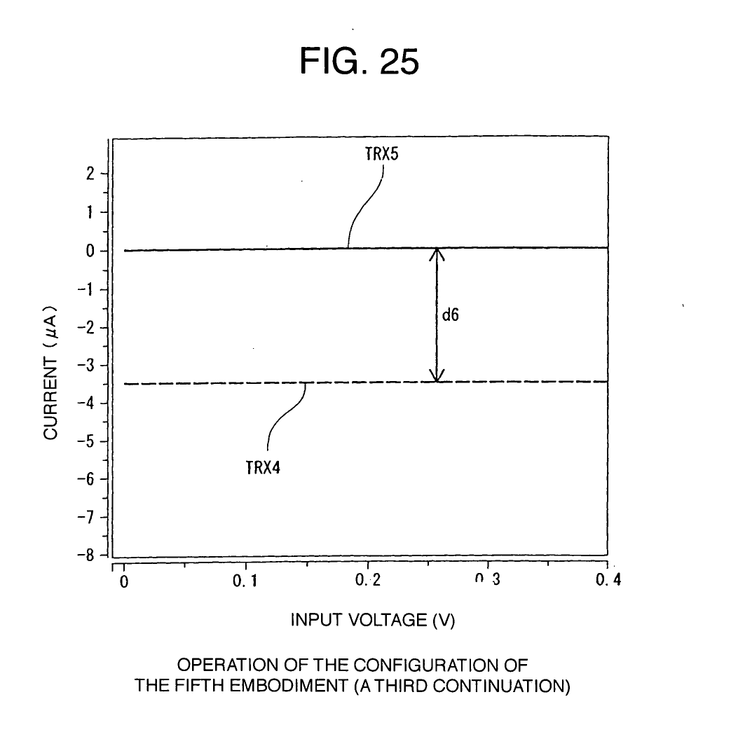

FIG. 24 is a graph showing the result of simulation of current consumption when the input voltage of the level shifter circuit 2200 rises. Further, FIG. 25 is an enlarged graph which compares the result of the simulation in FIG. 24 (when input signal IN is L level) with the level shifter circuit 1700 of the fourth embodiment. In FIGS. 24 and 25, a vertical axis shows a value of the current flowing out from the 3V power supply lines vdd3, and a horizontal axis shows the voltage of the input signal IN. Further, in FIG. 25, TRX4 corresponds to the level shifter circuit 1700 and TRX5 corresponds to the level shifter circuit 2200.

As is understood from FIG. 24, when the input signal IN rises from 0.5 V to 1.5 V, a current flows out from the 3V power supply line vdd3. Since the transistors 2201, 2211 operate at the same time even in this embodiment, a through current is not substantially generated.

Further, as is understood from FIG. 25, a minute current of the order of 3.5 μA is generated in the level shifter circuit 1700 even if the input signal IN is L level. On the other hand, a flowing current is exactly zero when the input signal IN in the level shifter circuit 2200 of this embodiment is L level. This is caused by the fact that the gate of the PMOS transistor 2211 is snot connected to the input terminal 121 but to the output terminal 122 in the level shifter circuit 2200 of this embodiment. That is, since the voltage of the output terminal 122 can be exactly zero volt by the NMOS transistor 102, if the gate of the PMOS transistor 2211 is connected to the output terminal, a through current can be prevented from generating with more certainty. In such a manner, the power consumption can be more reduced according to this embodiment compared with the foregoing embodiments.

As mentioned in detail above, according to this embodiment, it is possible to provide the level shifter circuit which is small in power consumption and speeded up in operating speed.

Sixth Embodiment:

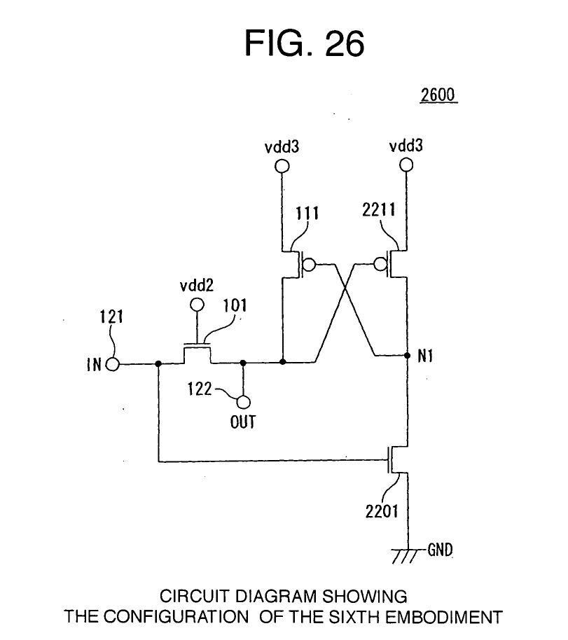

A level shifter circuit according to a sixth embodiment is now described with reference FIGS. 26 to 30.

FIG. 26 is a circuit diagram showing the configuration of a level shifter circuit 2600 of the embodiment. In FIG. 26, the constituents of the level shifter circuit 2600 which are the same as those of the level shifter circuit 2200 in FIG. 22 are depicted by the same reference numerals. That is, the level shifter circuit 2600 of the embodiment is different from the level shifter circuit 2200 in that the level shifter circuit 2600 has no NMOS transistor 102 (third transistor of the invention).

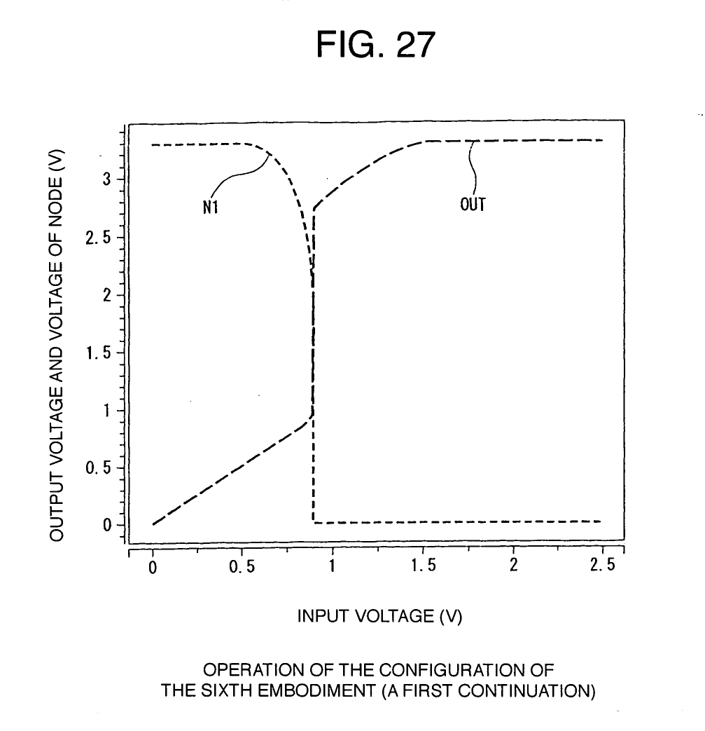

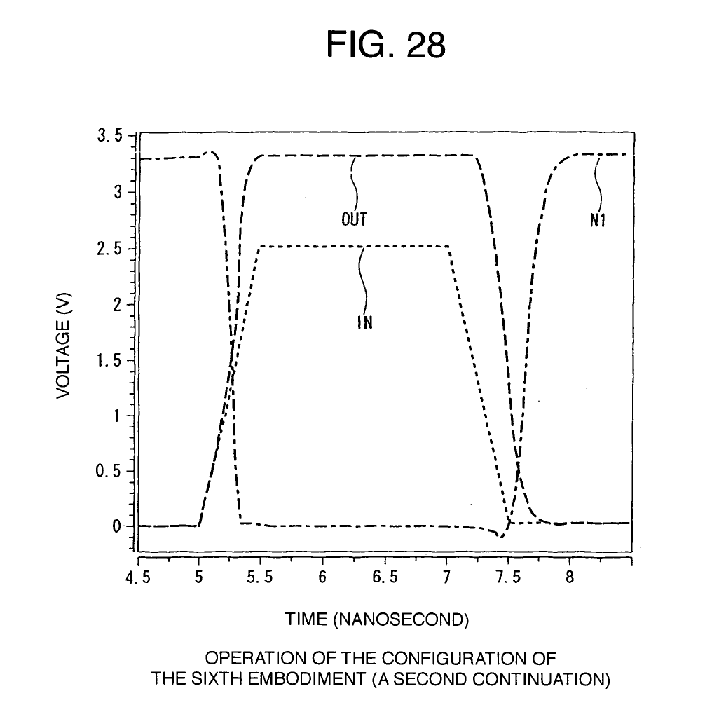

The operation of the level shifter circuit 2600 shown in FIG. 26 is now described with reference to FIGS. 27 and 28. FIGS. 27 and 28 are graphs showing the result of simulation of operation when an input voltage of the level shifter circuit 2600 rises. In FIG. 27, a vertical axis shows voltages of an output signal OUT and node N1, and a horizontal axis shows a voltage of an input signal IN. In FIG. 28, a vertical axis shows voltages of the input signal IN, output signal OUT and node N1, and a horizontal axis shows time.

Assume that, in the description set forth hereunder, a voltage supplied by a 2V power supply line vdd2 is H2 level, a voltage supplied by a 3V power supply line vdd3 is H3 level, and a voltage supplied by a ground line GND is L level.

Since an NMOS transistor 101 is connected to the 2V power supply line vdd2 at its gate, it is always ON. Accordingly, when the input signal IN is L level, the output signal OUT is L level. Further, since the input signal IN and output signal OUT are L level, an NMOS transistor 2201 is OFF and a PMOS transistor 2211 is ON. Accordingly, the voltage of the node N1 is H3 level. Consequently, a PMOS transistor 111 is OFF.

A case where the input signal IN rises from L level to H2 level is considered. In this case, the voltage of the output signal OUT starts to rise at the same time when the voltage of the input signal IN rises. Accordingly, the voltages of the gates of the transistors 2201, 2211 also rise. Subsequently, when the voltages of these gates are higher than an operating threshold voltage, the NMOS transistor 2201 turns ON and the PMOS transistor 2211 turns OFF. Consequently, the voltage of the node N1 drops, and hence the PMOS transistor 111 turns ON. As a result, the rise of the voltage of the output signal OUT is accelerated to reach H3 level. At this time, the input signal IN is held H2 level due to the effect of voltage drop at the stage of the NMOS transistor 101, and it does not rise up to H3 level. Accordingly, it does not exert an influence upon a pre-stage circuit of the level shifter circuit 2600.

A case where the input signal IN drops from H2 level to L level is next considered. In this case, the voltage of the output signal OUT starts to drop at the same time when the voltage of the input signal IN drops. Accordingly, the NMOS transistor 2201 turns OFF and the PMOS transistor 2211 turns ON, and hence the voltage of the node N1 rises up to H3 level. When the voltage of the node N1 reaches a threshold voltage, the PMOS transistor 111 turns OFF. As a result, the voltage of the output signal OUT drops to complete L level.

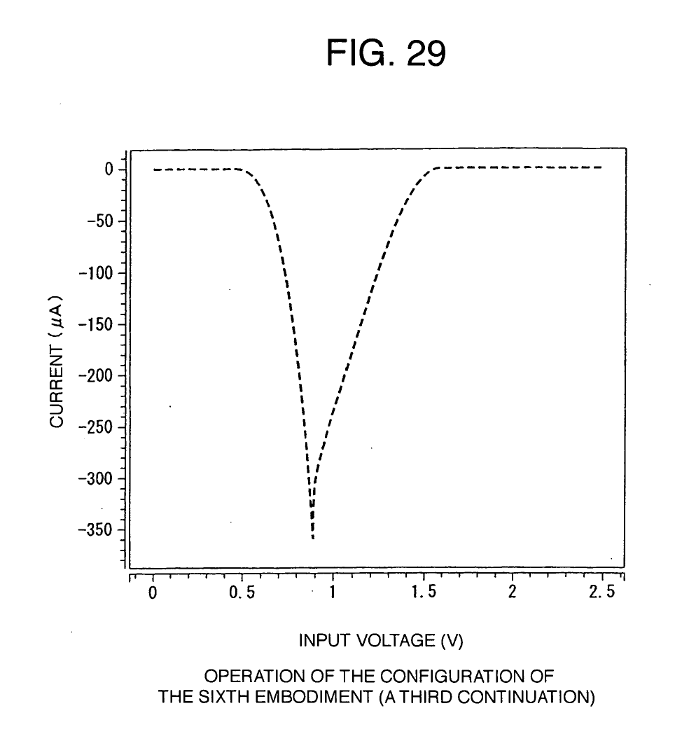

FIG. 29 is a graph showing the result of simulation of current consumption when the input voltage of the level shifter circuit 2600 rises. In FIG. 29, a vertical axis show a value of the current flowing out from the 3V power supply line vdd3, and a horizontal axis shows the voltage of the input signal IN.

As is understood from FIG. 20, when the input signal IN rises from 0.5 V to 1.5 V, the current flows out from the 3V power supply line vdd3. Since the transistors 2201, 2211 operate at the same time even in this embodiment, a through current is not substantially generated. Further, as is understood from FIG. 29, a power consumption is zero when the input signal IN is L level and H2 level. Accordingly, the power consumption of the level shifter circuit 2600 is very small.

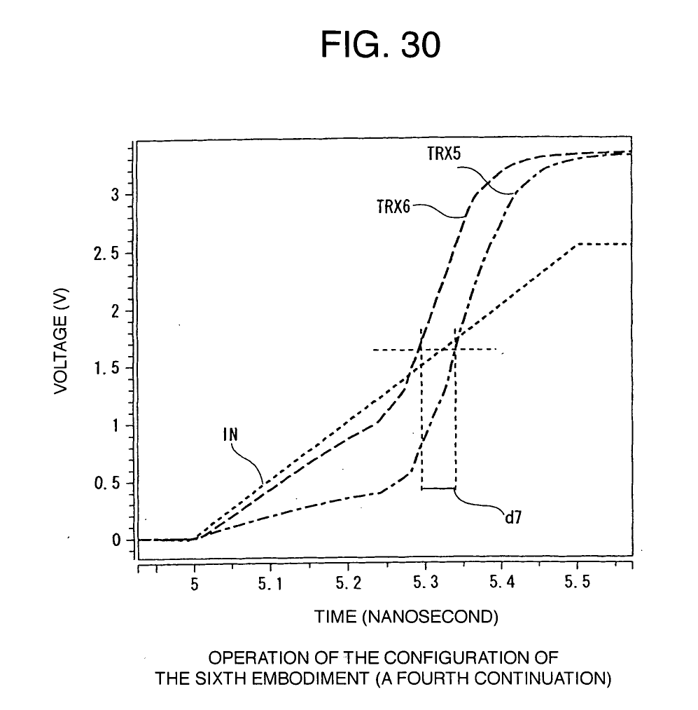

FIG. 30 is a graph showing the result of simulation of the operation of the level shifter circuit 2600 according to this embodiment compared with that of the level shifter circuit 2200 (see FIG. 22) of the fifth embodiment. FIG. 30 is a case where the voltage of the input signal IN rises. In FIG. 30, a vertical axis shows a voltage and a horizontal axis shows time. A curve TRX5 shows the output voltage of the level shifter circuit 2200 and a curve TRX6 shows the output voltage of the level shifter circuit 2600. Depicted by VDD3 is a supply voltage of the 3V power supply line vdd3.

As is understood from FIG. 30, according to the level shifter circuit 2600 of this embodiment, the voltage of the output signal OUT rises faster than that of the level shifter circuit 2200. The time required for the voltage of the output signal OUT in the level shifter circuit 2600 to reach VDD3/2 is shorter than that in the level shifter circuit 2200 by d7.

In such a manner, according to this embodiment, the operation time when the output signal OUT rises can be further speeded up. This is caused by the fact that the level shifter circuit 2600 of this embodiment has no NMOS transistor 102 whereupon a current flows out from the NMOS transistor 102 when the voltage of the output signal OUT rises in the level shifter circuit 2200 of the fifth embodiment.

As mentioned in detail above, according to this embodiment, it is possible to provide the level shifter circuit which is small in power consumption and speeded up in operating speed.

The invention can be applied not only to the level shifter circuit to be mounted on two power supply interface compatible semiconductor integrated circuit but also to other different types of level shifter circuits.

1. A level shifter circuit comprising:
a first power supply node to which a first power supply voltage is supplied;
a second power supply node to which a second power supply voltage, which is greater than the first power supply voltage, is supplied;
an input terminal to which an input signal of the first power supply voltage or an input signal of a ground voltage is inputted;
an output terminal from which an output signal of the second power supply or an output signal of the ground voltage is outputted;
an n-channel first transistor connected to said input terminal at its first electrode, to said output terminal at its second electrode, and to said first power supply node at its control electrode;
a p-channel second transistor connected to said second power supply node at its first electrode and to said output terminal at its second electrode; and
a control circuit for bringing said second transistor into conduction in response to the input signal of said first power supply voltage inputted to said input terminal, and bringing said second transistor out of conduction in response to the input signal of the ground voltage inputted to said input terminal.

2. The level shifter circuit according to claim 1, further comprising an n-channel third transistor connected to a ground node at its first electrode, to said output terminal at its second electrode, and to an output node of said control circuit at its control electrode.

3. The level shifter circuit according to claim 1, wherein said control circuit comprises:
an n-channel fourth transistor connected to a ground node at its first electrode, to an output node of said control circuit at its second electrode, and to said input terminal at its control electrode;
an n-channel fifth transistor connected to the ground node at its first electrode, to the output node at its second electrode, and to said output terminal at its control electrode; and
a p-channel sixth transistor connected to said second power supply node at its first electrode, to said output node at its second electrode, and to said output terminal at its control electrode.

4. The level shifter circuit according to claim 1, wherein said control circuit comprises:
an n-channel seventh transistor connected to a ground node at its first electrode, to an output node of said control circuit at its second electrode, and to said input terminal at its control electrode; and
a p-channel eighth transistor connected to said second power supply node at its first electrode, to said output node at its second electrode, and to said input terminal at its control electrode.

5. The level shifter circuit according to claim 1, wherein said control circuit comprises:
an n-channel ninth transistor connected to a ground node at its first electrode, to an output node of said control circuit at its second electrode, and to said input terminal at its control electrode; and
a p-channel tenth transistor connected to said second power supply node at its first electrode, to said output node at its second electrode, and to said output terminal at its control electrode.
g
